(19) United States
(12) Patent Application Publication
(10) Pub. No.: US 2024/0324466 A1
(43) Pub. Date: Sep. 26, 2024

(54) HIGH VOLTAGE FLEXIBLE MOLECULAR PIEZOELECTRIC DEVICES

(71) Applicant: UNIVERSITY OF PITTSBURGH - OF THE COMMONWEALTH SYSTEM OF HIGHER EDUCATION, Pittsburgh, PA (US)

(72) Inventors: Geoffrey R. Hutchison, Pittsburgh, PA (US); Christopher Andrew Petroff, Cheshire, CT (US)

(21) Appl. No.: 18/546,032

(22) PCT Filed: Feb. 10, 2022
(86) PCT No.: PCT/US2022/016007

§ 371 Date: Aug. 10, 2023

Related U.S. Application Data
(60) Provisional application No. 63/148,074, filed on Feb. 10, 2021.

(51) Int. Cl. H10N 30/857; H10N 30/077; H10N 30/30; H10N 30/87; H10N 30/88

(52) U.S. Cl. CPC H10N 30/857; H10N 30/077; H10N 30/302; H10N 30/877; H10N 30/883

(57) ABSTRACT

A flexible biocompatible material, comprising: an oligopeptide self-assembled monolayer disposed/deposited on a first electrode; and a dielectric layer disposed/deposited over and/or attached to the oligopeptide self-assembled monolayer and the first electrode.

### RELATED APPLICATION

This application claims priority benefit under 35 U.S.C. § 119(e) of U.S. Provisional Application No. 63/148,074 filed Feb. 10, 2021 the contents of which are herein incorporated by reference.

### FIELD OF THE DISCLOSURE

### Technical Field

The present disclosure relates to flexible, bio-compatible piezoelectric materials that are of considerable research interest for a variety of applications, but many suffer from low response or high cost to manufacture.

### Background

Presented herein are novel piezoelectric force and touch sensors based on self-assembled monolayers of oligopeptides which produce large piezoelectric voltage response and are easily manufactured without the need for electrical poling.

Piezoelectric materials find use in a wide range of applications from sensors' to energy harvesters² to actuators.³ These devices rely on the piezoelectric effect to interconvert mechanical stress and electrical charge. In the direct piezoelectric effect, an applied force produces a resultant charge, whereas, in the converse effect, an applied voltage causes a mechanical deformation. Most existing piezoelectric materials are hard, brittle, lead-containing ceramics such as lead zirconium titanate (PZT).⁴ As such, these materials have limited ranges of motion, are liable to crack, and are not bio-compatible. While there is a large research focus on developing flexible, bio-compatible piezoelectric materials,⁵ much of this work has involved placing traditional piezoelectrics on or into flexible substrates, often sacrificing electrical performance for added flexibility and ease of manufacturing (i.e., δ-values <200 pC/N instead of 500 pC/N-600 pC/N for PZT).^{2,6,7} In addition to well known piezoelectric polymers such as semi-crystalline poly(vinylidene fluoride) (PVDF), researchers have begun to develop fundamentally new piezoelectric materials such as helicenes, amino acids, viruses, and peptides. 5,8-12

While the most commonly reported piezoelectric constant is the piezoelectric charge constant, δ, the piezoelectric voltage constant, γ, is perhaps more meaningful for sensing applications, since large voltages can be easily and accurately detected.^{1,11,13-15} Despite its importance, there are few examples of the voltage constant reported in the literature, making device comparisons difficult (see Guerin et al.¹⁵ and Chen et al.¹⁶ as examples). When both polarization and stress are along the Z-axis, the subscript 33 is used (i.e., δ₃₃ and γ₃₃). The piezoelectric charge and voltage constants are related by the relative permittivity such that g₃₃=d₃₃/εᵣε₀, where εᵣ is the relative permittivity of the material and _{ε0} is the vacuum permittivity.¹⁷ As such, low dielectric constant organics have the potential to produce high-response piezoelectric sensors.¹⁵ The piezoelectric voltage constant is often calculated from the piezoelectric charge constant, or it can be measured directly from applied stress and resulting electric field. Direct measurements are perhaps more meaningful for low-frequency sensing applications, as conversions are often calculated using the relative permittivity for a higher frequency, which may or may not translate to real-world use at lower frequencies.

Piezoelectricity occurs naturally in the body and plays an important role in processes such as bone growth.⁵ While it has been demonstrated that amino acids and peptides are piezo-active,⁵ significant challenges exist in applying them to usable devices, including aligning the materials or crystals to produce a bulk piezoelectric response by means of an external high-voltage electric field.⁵

### Promise of Piezoelectric Self-Assembled Monolayers

Self-assembled monolayers (SAMs) are a promising approach to bulk alignment of piezoelectric molecules^{18,19} and thus piezoelectric SAM (PSAM) devices of the present disclosure are preferably based on self-assembled oligopeptide monolayers. SAMs have been widely studied, and thiol-containing molecules are known to form uniform, stable monolayers on gold substrates.²⁰ Self-assembled piezoelectric devices present significant advantages over more traditional approaches as they are intrinsically polar and can be easily produced through solution processing.

While preferred devices of the present disclosure generate modest piezoelectric charge constants (d33) of up to 9.8 pC/N, they exhibit immense piezoelectric voltage constants (g33) up to 2 Vm/N. Furthermore, a flexible device of the present disclosure produces open-circuit voltages of nearly 6 V under gentle bending motion. Improvements in peptide selection and device construction promise to further improve the already outstanding voltage response and open the door to numerous practical applications.

### BRIEF SUMMARY OF THE DISCLOSURE

A first aspect of a preferred embodiment of the present disclosure comprises a flexible biocompatible material, comprising: an oligopeptide self-assembled monolayer disposed/deposited on a first electrode; and a dielectric layer disposed/deposited over and/or attached to the oligopeptide self-assembled monolayer and the first electrode.

Another aspect of a preferred embodiment of the present disclosure comprises a flexible biocompatible material, comprising: an oligopeptide self-assembled monolayer disposed/deposited on a first printed circuit board; and a dielectric layer disposed/deposited over and/or attached to the oligopeptide self-assembled monolayer and the first printed circuit board.

In another aspect of a preferred flexible biocompatible material of the present disclosure, the dielectric layer comprises polyurethane, a polyurethane film or other suitable polymer or polymer film or a non-polymer material.

In yet another aspect of a preferred flexible biocompatible material of the present disclosure, the dielectric layer has a thickness of about 40 μm.

In another aspect of a preferred flexible biocompatible material of the present disclosure, the dielectric layer has a thickness of about 23 μm.

In yet another aspect of a preferred flexible biocompatible material of the present disclosure, the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

In another aspect of a preferred flexible biocompatible material of the present disclosure, the oligopeptide self-assembled monolayer is carboxylate terminated or amide terminated.

Another aspect of a preferred embodiment of the present disclosure comprises a piezoelectric self-assembling monolayer device, comprising: a flexible biocompatible material of claim 1 having a second electrode or second printed circuit board sealed over or on top of the dielectric layer.

In another aspect of a preferred piezoelectric self-assembling monolayer device of the present disclosure, the dielectric layer is used to adhere or attach the second electrode or second printed circuit board to the oligopeptide self-assembled monolayer and the first electrode or first printed circuit board and to seal the device from the atmosphere.

In yet another aspect of a preferred piezoelectric self-assembling monolayer device of the present disclosure, the dielectric layer comprises polyurethane, a polyurethane film or other suitable polymer or polymer film or a non-polymer material.

Another aspect of a preferred embodiment of the present disclosure comprises a flexible sealed piezoelectric device, comprising: a first electrode layer or a first printed circuit board layer adhered to a flexible substrate by an adhesion layer; wherein the adhesion layer is disposed/deposited between the flexible substrate and the first electrode layer or the first printed circuit board layer; an oligopeptide self-assembled monolayer disposed/deposited on the first electrode layer or first printed circuit board layer; and a second electrode layer or second printed circuit board layer adhered to and sealed to the oligopeptide self-assembled monolayer and the first electrode layer or the first printed circuit board layer by a dielectric layer disposed/deposited over and attached to the oligopeptide self-assembled monolayer and the first electrode layer or the first printed circuit board layer.

In yet another aspect of a preferred flexible sealed piezoelectric device of the present disclosure, the flexible substrate comprises a polymer or plastic coverslip such as a Nunc Thermanox Plastic Coverslip available from Thermo Scientific.

In another aspect of a preferred flexible sealed piezoelectric device of the present disclosure, the adhesion layer comprises titanium.

In yet another aspect of a preferred flexible sealed piezoelectric device of the present disclosure, the adhesion layer has a thickness of about 10 nm.

In another aspect of a preferred flexible sealed piezoelectric device of the present disclosure, the first electrode layer or first printed circuit board layer comprises gold.

In yet another aspect of a preferred flexible sealed piezoelectric device of the present disclosure, the first electrode layer or the first printed circuit board layer has a thickness of about 100 nm.

In another aspect of a preferred flexible sealed piezoelectric device of the present disclosure, the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

In another aspect of a preferred flexible sealed piezoelectric device of the present disclosure, the dielectric layer comprises polyurethane, a polyurethane film or other suitable polymer or polymer film or a non-polymer material.

In yet another aspect of a preferred flexible sealed piezoelectric device of the present disclosure, the oligopeptide self-assembled monolayer is carboxylate terminated or amide terminated.

Another aspect of a preferred embodiment of the present disclosure comprises a force/touch sensor comprising: an oligopeptide self-assembled monolayer disposed/deposited on an electrode or a printed circuit board; and a dielectric layer disposed/deposited over the oligopeptide self-assembled monolayer and the electrode or printed circuit board.

In another aspect of a preferred force/touch sensor of the present disclosure, the dielectric layer comprises polyurethane, a polyurethane film or other suitable polymer or polymer film or a non-polymer material.

In another aspect of a preferred force/touch sensor of the present disclosure, the dielectric layer has a thickness of about 40 μm.

In another aspect of a preferred force/touch sensor of the present disclosure, the dielectric layer has a thickness of about 23 μm.

In another aspect of a preferred force/touch sensor of the present disclosure, the the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

In another aspect of a preferred force/touch sensor of the present disclosure, the oligopeptide self-assembled monolayer is carboxylate terminated or amide terminated.

Another aspect of a preferred embodiment of the present disclosure comprises a method for making a flexible sealed piezoelectric device/sensor, comprising: depositing an adhesion layer on a flexible substrate; depositing a first electrode layer or printed circuit board layer on the adhesion layer; forming an oligopeptide self-assembled monolayer on the first electrode layer or first printed circuit board layer; coating the oligopeptide self-assembled monolayer with a liquid solution of dielectric material; placing a second electrode layer or a second printed circuit board layer onto the liquid solution of dielectric material; and compressing the second electrode layer or second printed circuit board layer against the liquid solution of dielectric material until the liquid solution of dielectric material dries or cures.

In another aspect of a preferred method for making a flexible sealed piezoelectric device/sensor of the present disclosure, the flexible substrate comprises a polymer or plastic coverslip such as a Nunc Thermanox Plastic Coverslip available from Thermo Scientific.

In another aspect of a preferred method for making a flexible sealed piezoelectric device/sensor of the present disclosure, the adhesion layer comprises titanium.

In another aspect of a preferred method for making a flexible sealed piezoelectric device/sensor of the present disclosure, the adhesion layer has a thickness of about 10 nm.

In another aspect of a preferred method for making a flexible sealed piezoelectric device/sensor of the present disclosure, the first electrode layer or first printed circuit board layer comprises gold.

In another aspect of a preferred method for making a flexible sealed piezoelectric device/sensor of the present disclosure, the first electrode layer or the first printed circuit board layer has a thickness of about 100 nm.

In another aspect of a preferred method for making a flexible sealed piezoelectric device/sensor of the present disclosure, the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

In another aspect of a preferred method for making a flexible sealed piezoelectric device/sensor of the present disclosure, the liquid solution of dielectric material comprises polyurethane, or other suitable polymer or a non-polymer material.

In another aspect of a preferred method for making a flexible sealed piezoelectric device/sensor of the present disclosure, the oligopeptide self-assembled monolayer is carboxylate terminated or amide terminated.

In another aspect of a preferred method for making a flexible sealed piezoelectric device/sensor of the present disclosure, the coating is performed by drop casting the liquid solution of dielectric material onto the oligopeptide self-assembled monolayer.

In another aspect of a preferred method for making a flexible sealed piezoelectric device/sensor of the present disclosure, the liquid solution of dielectric material adheres to and attaches the second electrode layer or second printed circuit board layer to the oligopeptide self-assembled monolayer and the first electrode layer or first printed circuit board layer and seals the device/sensor from the atmosphere.

Another aspect of a preferred embodiment of the present disclosure comprises a method for making a piezoelectric self-assembling monolayer device, comprising: forming an oligopeptide self-assembled monolayer on a first conductive layer or a first printed circuit board layer; coating the oligopeptide self-assembled monolayer with a liquid solution of dielectric material; placing a second conductive layer or a second printed circuit board layer onto the liquid solution of dielectric material; and compressing the second conductive layer or the second printed circuit board layer against the liquid solution of dielectric material until the liquid solution of dielectric material dries or cures.

In another aspect of a preferred method for making a piezoelectric self-assembling monolayer device of the present disclosure, the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

In another aspect of a preferred method for making a piezoelectric self-assembling monolayer device of the present disclosure, the liquid solution of dielectric material comprises polyurethane or other suitable polymer or a non-polymer material.

In another aspect of a preferred method for making a piezoelectric self-assembling monolayer device of the present disclosure, the oligopeptide self-assembled monolayer is carboxylate terminated or amide terminated.

In another aspect of a preferred method for making a piezoelectric self-assembling monolayer device of the present disclosure, the coating is performed by spraying the liquid solution of dielectric material onto the oligopeptide self-assembled monolayer.

In another aspect of a preferred method for making a piezoelectric self-assembling monolayer device of the present disclosure, the liquid solution of dielectric material adheres to and attaches the second conductive layer or second printed circuit board to the oligopeptide self-assembled monolayer and the first conductive layer or first printed circuit board and seals the device from the atmosphere.

### BRIEF DESCRIPTION OF THE DRAWINGS

The present disclosure is illustrated by way of example and not limitation in the figures of the accompanying drawings, in which:

FIGS. 1A and 1B show a generalized scheme outlining PSAM devices of the present disclosure;

FIGS. 2A and 2B show the piezoelectric charge response for devices of the present disclosure;

FIGS. 3A and 3B show the piezoelectric voltage response of preferred devices of the present disclosure;

FIGS. 4A and 4B show the effect of PU thickness on preferred devices of the present disclosure;

FIGS. 5A, 5B and 5C show a flexible sealed PSAM device (CA12-NH2/DDT-PU) fabricated on gold-coated plastic substrates according to the present disclosure;

FIGS. 6A and 6B illustrate the process by which the piezoelectric charge constant_{(d33)} is obtained for a CA₆-NH2/DDT-PU PSAM device of the present disclosure;

FIGS. 7A and 7B illustrate the process by which the piezoelectric voltage constant_{(g33)} is obtained for a CA12-NH2/thin-PU PSAM device of the present disclosure;

FIG. 8 shows piezoelectric charge constant_{(d33)} values for 1-dodecanethiol (DDT) control PSAM devices of the present disclosure;

FIG. 9 shows the piezoelectric voltage constant_{(g33)} values for 1-dodecanethiol (DDT) control PSAM devices of the present disclosure;

FIGS. 10A and 10B show that samples of the present disclosure retain piezoelectric response over several months of storage in a vacuum desiccator wherein FIG. 10A shows a response grouped by sample and FIG. 10B shows a response as a function of storage time.

FIG. 11 shows the piezoelectric voltage constants_{(g33)} of sealed PSAM devices of the present disclosure;

FIG. 12 shows that sealed PSAM devices of the present disclosure retain response over 18 d and approximately 900 test cycles under ambient conditions;

FIG. 13 shows atomistic visualization of the carboxylate-terminated peptide CA₆ in liquid water from room-temperature ab initio molecular dynamics simulations;

FIG. 14 shows probability distributions of the lengths of the four H-bonds characterizing the a-helix structure of the carboxylate-terminated peptide (CA6; solid blue curves) and the amide-terminated peptide (CA6 am; dashed yellow curves), as determined by ab initio molecular dynamics simulations in the zero-field regime (i.e., E=0.0 V/nm);

FIG. 15 shows probability distributions of the lengths of the four H-bonds characterizing the a-helix structure of the carboxylate-terminated peptide CA₆ in the zero-field regime (solid black curves) and at field strengths of 0.5 V/nm (dashed blue curves) and 1.0 V/nm (dotted red curves), as determined by ab initio molecular dynamics simulations; and

FIG. 16 shows probability distributions of the lengths of the four H-bonds characterizing the a-helix structure of the amide-terminated peptide CA6-NH2 in the zero-field regime (solid black curves) and at field strengths of 0.5 V/nm (dashed blue curves) and 1.0 V/nm (dotted red curves), as determined by ab initio molecular dynamics simulations.

### DETAILED DESCRIPTION OF PREFERRED EMBODIMENTS

The following description, taken in conjunction with the referenced drawings, is presented to enable one of ordinary skill in the art to make and use the disclosure and to incorporate it in the context of particular applications. Various modifications, as well as a variety of uses in different applications, will be readily apparent to those skilled in the art, and the general principles, defined herein, may be applied to a wide range of aspects. The present disclosure is not intended to be limited to the aspects disclosed herein. Instead, it is to be afforded the widest scope consistent with the disclosed aspects.

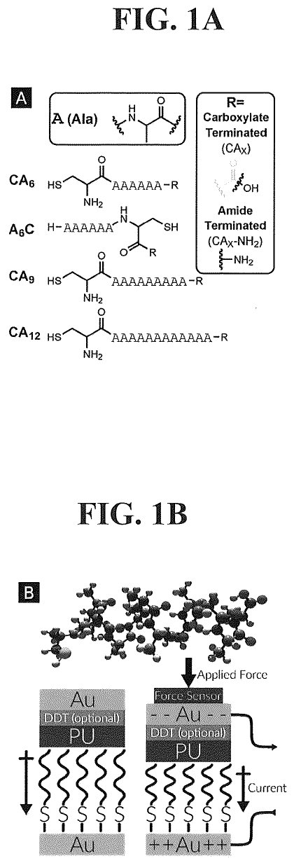

SAMs of thiol-containing oligopeptides, ranging in length from seven to thirteen amino acids were formed from solution on gold-coated printed circuit boards (PCBs). The peptide sequences, shown in FIG. 1A, consist of cysteine (C) and six, nine, or twelve alanines (A); both carboxylate-terminated and amide-terminated forms were studied for most sequences. As illustrated in FIG. 1b, assemblies of a peptide functionalized PCB facing a polyurethane (PU) coated PCB were tested in a quasi-static manner using an automated system. Piezoelectric constants were subsequently calculated from these data. Moreover, state-of-the-art ab initio molecular dynamics (AIMD) simulations were carried out in order to help interpret, on a microscopic basis, some of the experimental results.

### Piezoelectric Charge Constant

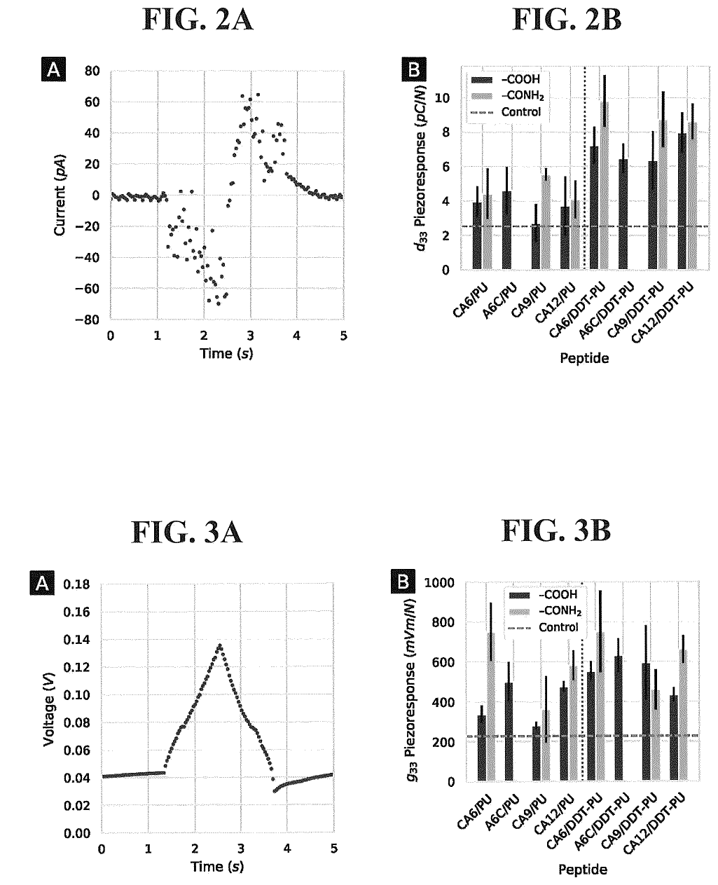

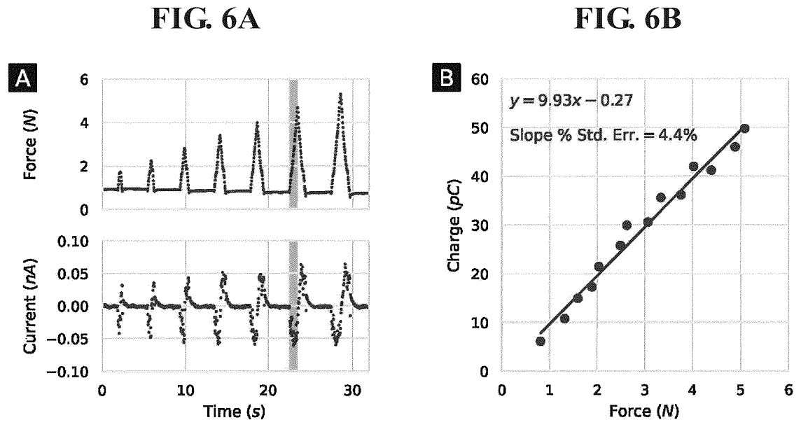

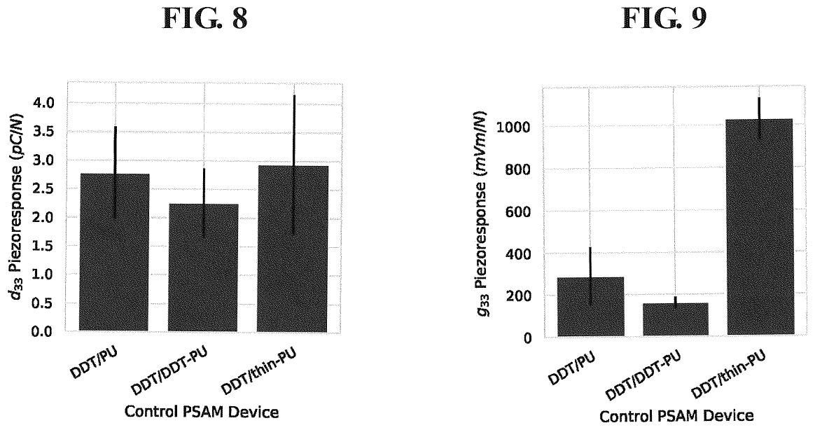

The peptides used are helical and should act as “molecular springs”^{18,21,22} when compressed, leading to much greater length changes than similar linear molecules such as the 1-dodecanethiol (DDT) used as a control. As the length of each peptide changes, so too does its dipole; therefore, when a force is applied to compress these “springs,” charge builds up on the surface, leading to a measurable piezoelectric response.^{18,21,22} The piezoelectric charge constant_{(δ33)} is calculated by integrating the measured current and plotting the resultant charge versus the applied force (FIG. 6); since there is no convention for defining the positive Z-axis in our self-assembled, non-crystalline materials, we used the absolute value of charge. FIG. 2 presents a summary of δ33 values obtained for our PSAM devices. Computed_{δ33} values for peptide assemblies are consistently higher than those of the alkanethiol controls (FIG. 8). A small piezoelectric response is expected for DDT because SAMs contain an interface and are, therefore, inherently piezoelectric.²³ A maximum value of (9.8±1.5) pC/N is obtained for the assembly consisting of amide-terminated CA₆ functionalized PCBs opposing PU coated DDT functionalized PCBs (CA₆-NH2/DDT-PU). On average, peak current values of 80 pA-100 pA were observed at the maximum applied force of <6 N.

FIGS. 1A and 1B show a generalized scheme outlining PSAM devices of the present disclosure wherein FIG. 1A shows chemical structures of peptides used. FIG. 1B shows a 3D structure of α-helical peptide CA12 (top) and a schematic diagram showing an applied force compressing a PSAM device of the present disclosure, changing the dipole moment, and leading to the buildup of charge and subsequent flow of current (bottom).

We experimentally examined several variations of our PSAM devices and used analysis of variance (ANOVA) to look and see how and if these changes affect the piezoelectric response in a statistically significant fashion (see Supplementary Tables 1-12). Firstly, we varied the PCB opposing the peptide PCB in the device. These PCBs were coated in PU, and we looked at both unfunctionalized and DDT functionalized versions. With nearly double the response, peptides tested against PCBs where the PU layer coats a DDT monolayer (average 833 of 7.9 pC/N) produced statistically higher responses than peptides tested against PCBs where the PU layer coats bare gold (average d₃₃ of 4.1 pC/N). While this difference in piezoelectric response is somewhat unexpected, we theorize the DDT may affect the organization and properties of the PU layer, thereby altering the piezoelectric responses of the devices.

FIGS. 2A and 2B show the piezoelectric charge response for devices of the present disclosure wherein FIG. 2A shows a representative short-circuit current measurement for one compression of a PSAM device. FIG. 2B shows the piezoelectric charge constants (δ₃₃) of PSAM devices containing PU coated DDT PCBs are greater than those containing PU coated unfunctionalized PCBs. Amide-terminated peptides present higher responses than carboxylate-terminated ones. Peptide responses are greater than those of DDT controls (dashed line; see FIG. 8). Error bars represent standard error across multiple samples.

Next, we analyzed the difference in piezoelectric response between carboxylate-terminated and amide-terminated peptides. The amide-terminated peptides appear to produce (P-value <0.05) statistically greater piezoelectric responses than carboxylate-terminated peptides do; this is counter intuitive at first, as the amide-terminated form should have a smaller dipole moment, but the amide-termination may also affect the tilt angle of the SAM or the stability and rigidity of the a-helix. If the amide causes the SAM to stand more perpendicular to the surface, this can counteract the effect of a smaller dipole by increasing the effective dipole in the Z-direction. Additionally, if the cx-helices of the amide-terminated peptides are less rigid, they will deform more easily under compression, leading to a greater change in dipole and, therefore, greater piezoelectric response.

Finally, we looked at varying the peptide sequence to alter its length; we tested CA₆, A₆C, CA₉, and _{CA12} sequences. Somewhat surprisingly, the length of the peptide did not statistically alter the measured response despite the length-dictated dipole differences. Several explanations exist for the analogous values: they are similar because the longer peptides may not stand as straight on the surface, leading to a lower response in the Z-direction; the SAMs of the longer peptides may pack less densely, leading to lower response per unit area; and/or the responses are dominated by the hydrogen bonding of the α-helices of the peptide backbone, which may be invariant of the peptide length.

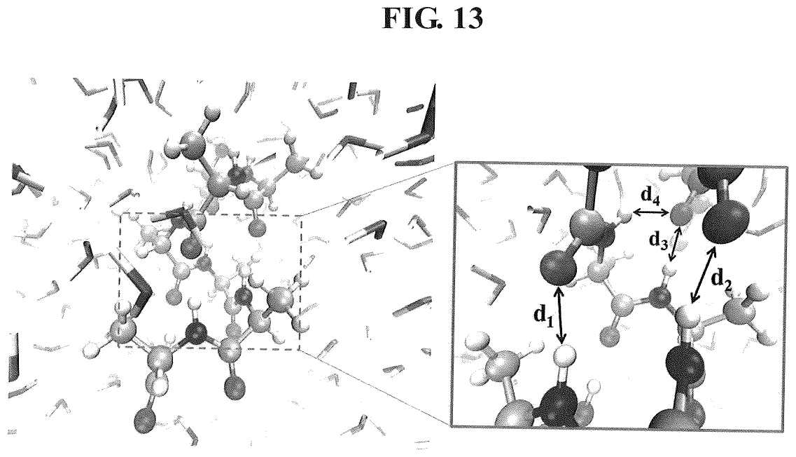

We turned to AIMD simulations to help explain our experimental results. We examined the carboxylate-terminated CA₆ sequence and the corresponding amide-terminated CA₆-NH₂ sequence. The modeling shows that the piezoelectric responses of our peptides are largely dependent on the strength of the hydrogen bonds in the α-helices of the peptide backbones. The backbone of the carboxylate-terminated peptides was found to be more stable and rigid than its amide-terminated counterpart. Furthermore, higher applied electric fields were needed before the carboxylate-terminated peptide deformed. These data agree favorably with our experimental results, which show that the amide-terminated peptides produce higher response than the carboxylate-terminated peptides and suggest that the length of the peptide plays a relatively minor role in the overall piezoelectric response. For a more detailed, quantitative discussion of the AIMD results, see the Supplementary Note below and FIGS. 13-16.

### Piezoelectric Voltage Constant

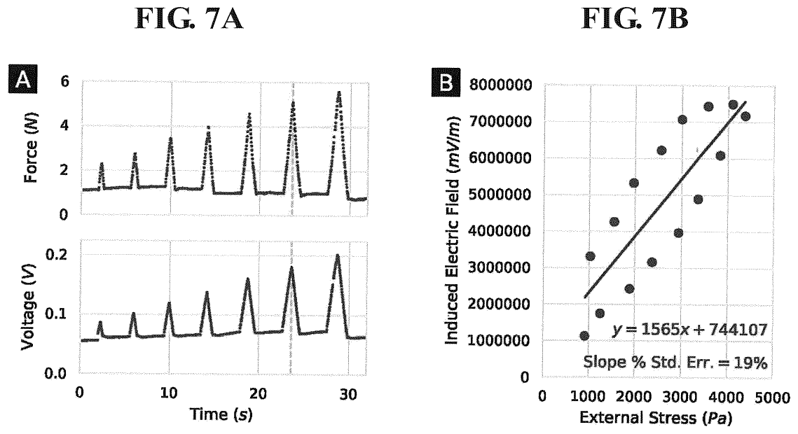

Our PSAM devices show great potential as piezoelectric sensors as demonstrated by their high piezoelectric voltage constants (g₃₃). These voltage constants are calculated by plotting induced electric field (measured voltage divided by sample thickness) against external stress (applied force divided by sample area) and determining the linear fit (FIG. 7). As shown in FIG. 3, g₃₃ values up to (750±150) mVm/N were obtained; for comparison, this is an order of magnitude greater than the _{g33} value of <40 mVm/N for PZT^{24,25} and is also greater than the predicted g₃₃ value of '480 mVm/N for a racemic alanine crystal.¹¹ As expected, the measured _{g33} values are greater than those obtained for alkanethiol controls (FIG. 9). While the oft reported peak voltage produced by piezoelectric devices is important for showing their potential practical use, the voltage value is affected by many factors including the device area and thickness as well as the force applied, making it difficult to compare devices reported in the literature. For example, we saw, on average, a peak voltage of '0.2 V at the maximum applied force of 6 N, but if we had only applied 3 N of force, the maximum voltage would have only been '0.1 V. In contrast, the piezoelectric voltage constant (g)—the voltage analog of the ubiquitous piezoelectric charge constant (d)—allows for meaningful comparisons of sensing potential but is, unfortunately, largely absent from the literature.

While we initially planned to examine the voltage response of our PSAM devices analogously to our approach for the charge response, the results are more varied and less conclusive. Although the same trends—greater DDT-PU response, greater amide-termination response, and no length effect—are present, they are not statistically significant. To help explain this incongruity, we examined the difference in response between individual PU and DDT-PU PCBs. While the different PCBs within each category were statistically similar for values of the piezoelectric charge constant, the piezoelectric voltage constant values obtained for individual DDT-PU PCBs were statistically different. This lack of uniformity is likely because capacitive and leakage effects hold a greater role in the voltage measurements and quite possibly vary PCB to PCB due to defects in the dielectric layer.

FIGS. 3A and 3B shows the piezoelectric voltage response of preferred devices of the present disclosure wherein FIG. 3A shows a representative open-circuit voltage measurement for one compression of a PSAM device. Note that the baseline has been corrected. FIG. 3B shows the piezoelectric voltage constants _{γ33} of PSAM devices. Peptide responses are greater than those of DDT controls (dashed line; see FIG. 9). Error bars represent standard error across multiple samples.

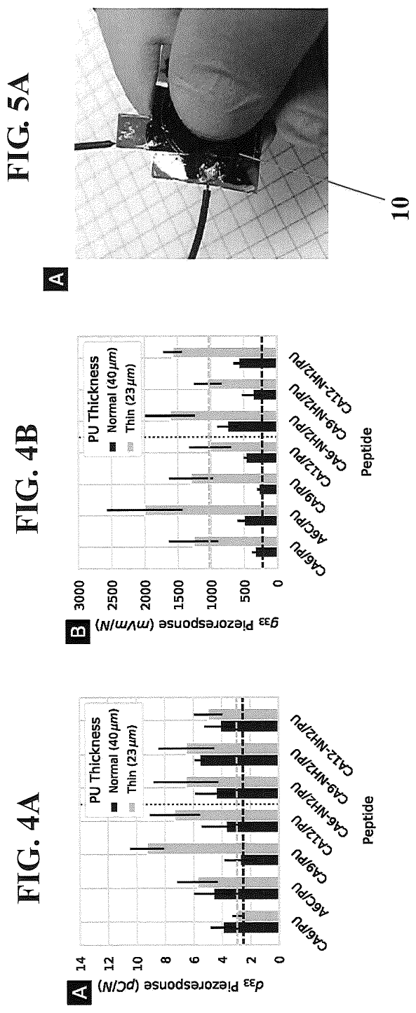

The induced electric field plays a critical role in the magnitude of the piezoelectric voltage constant; it is dependent on both the measured voltage and the device thickness. For our PSAM devices, we calculated the induced electric field based on the distance between the electrodes; this distance is almost entirely dictated by the thickness of our PU dielectric layer, whereas the absolute voltage should be largely independent of thickness. Accordingly, we looked to increase our induced electric field and piezoelectric voltage constant by decreasing the PU thickness. We accomplished this by diluting our PU with petroleum ether before spin-coating. When we tested our peptides against these thinner dielectric layers, we observed a much greater piezoelectric voltage response (FIG. 4); unexpectedly, we also saw an increase in the piezoelectric charge response. It is unknown how the petroleum ether used to reduce the PU thickness affected the spin coating, drying, and final properties of the PU dielectric layer; the PCBs with the thinner PU coating were less consistent, as we observed statistical differences between the individual PCBs in both the piezoelectric charge and voltage constants. We suspect that changes to the PU dielectric layer resulted in the statistically greater piezoelectric charge constant (833) values for PSAM devices containing these thinner PU PCBs; the charge constant should be largely independent of the thickness of the dielectric layer. Nonetheless, the _{γ33} values obtained for thin PU PSAM devices are considerably greater than the change in _{δ33} values alone can account for. Since the thin PU layer is nearly half the thickness of the normal PU layer, we expect the resultant PSAM devices to have almost twice the voltage response. Indeed, the _{γ33} values of up to (2000±600) mVm/N observed for the thin PU PSAM devices agree, within error, to those expected from the combination of the _{δ33} increase and the PU thickness decrease; on average, the γ33 values for the PSAM devices containing PCBs with the thinner PU coating were (220±40) % greater than those with the normal thickness PU, whereas the expected increase based on the combination of _{δ33} increase (60±30)% and thickness decrease (74±2)% is (180±60)%. The maximum _{γ33} value of 2 Vm/N is quite remarkable and, to the best of our knowledge, is the highest experimental value reported to date in the literature.

### Device Stability

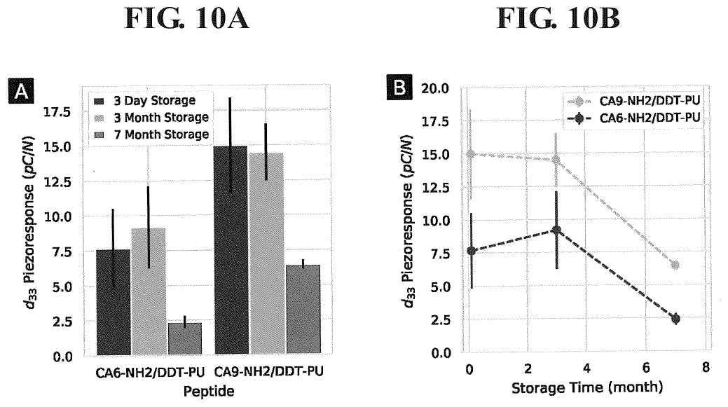

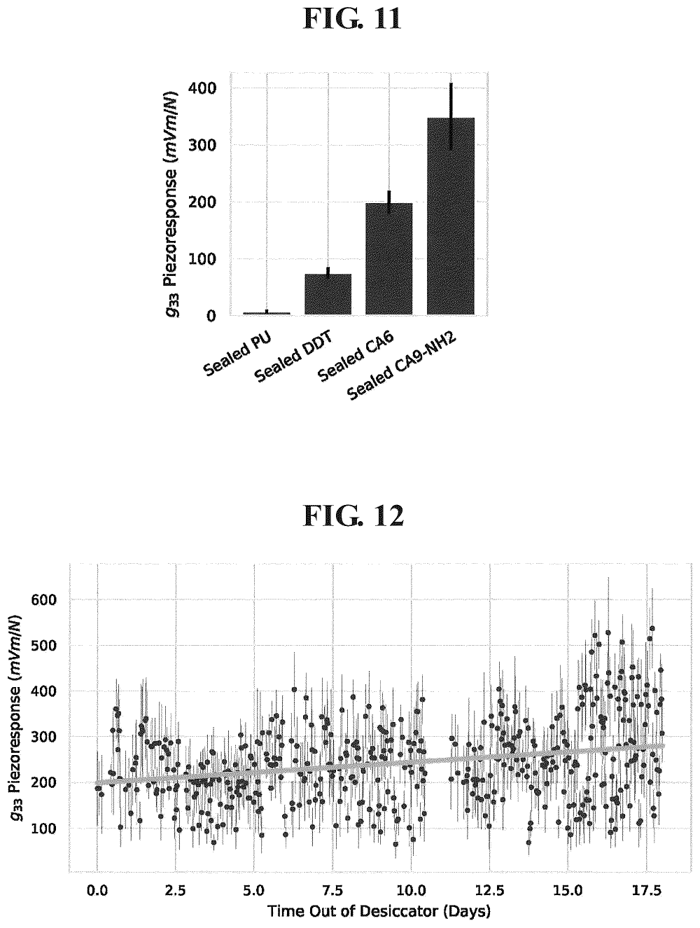

The long-term stability of piezoelectric devices is of importance to their practical adoption; as such, we measured the stability of the piezoelectric response of our devices in multiple ways. Our PSAM devices show remarkable stability and retain their initial piezoelectric response for at least three months when stored away from light in a vacuum desiccator (FIG. 10); this is in line with the expected stability of SAMs under these storage conditions. While the long-term storage stability is adequate, the response of our normal PSAM devices decays over a matter of hours when exposed to ambient conditions. In order to solve this problem, we produced sealed PSAM devices where we placed the two PCBs together before the PU dried. The active layer of these sealed PSAM devices is protected from the atmosphere. When we tested these devices, we found that, while the charge response was much lower, the voltage response was similar to that of our normal PSAM devices due to the thinner PU layer (FIG. 11). On the stability front, the response actually increased over several weeks of testing (FIG. 12). Some of the observed increase in response is due to the slight decrease in preload force overtime due to the nature of our testing setup; the rest of the increase might be due to organizing effects in the monolayer over time. These results show that, with improved manufacturing methods, our PSAM devices have real potential in practical applications.

FIGS. 4A and 4B show the effect of PU thickness wherein FIG. 4A shows the piezoelectric charge constants _{γ33} of PSAM devices of the present disclosure using normal thickness PU (40 μm) compared with those using thinner PU (23 μm). FIG. 4B shows the piezoelectric voltage constants _{γ33} of PSAM devices of the present disclosure using normal thickness PU compared with those using thinner PU. The dashed lines show the piezoelectric response of DDT controls (see FIGS. 8 and 9) where navy corresponds to the normal thickness and gold corresponds to the thinner thickness. Error bars represent standard error across multiple samples.

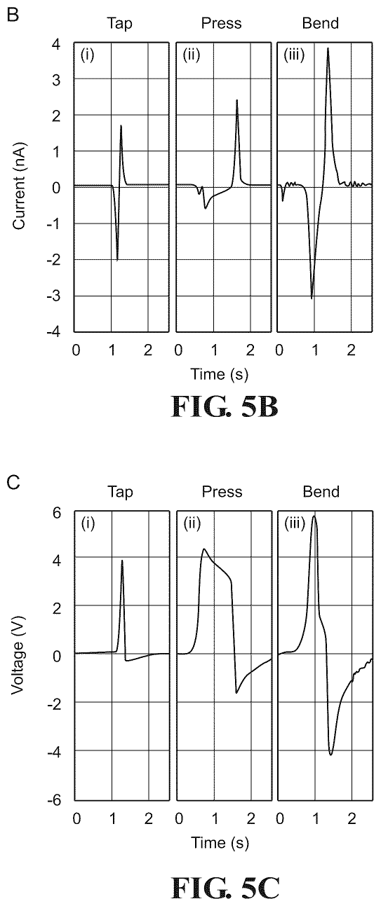

To further demonstrate the potential practical application of preferred PSAM devices of the present disclosure, a sealed device made using flexible, gold-coated substrates was constructed according to the present disclosure. When tested using our normal method, we measured a _{γ33} value of (3.68±0.08) pC/N and a _{γ33} value of (35±4) mVm/N (the PU layer is an order of magnitude thicker, but its thickness and uniformity are somewhat uncertain). In addition, we examined our flexible device under more practical conditions by measuring its current and voltage in response to finger taps, presses, and bends (FIG. 5). The finger taps and presses led to maximum currents of approximately 2 nA and voltages of approximately 4 V, whereas the bends produced almost 4 nA and 6 V. These values are much greater than those obtained when the device is tested normally (0.006 nA/0.06 V) and are likely due to the more localized nature of the force. The measured voltage response is much greater than that of most flexible devices reported in the literature while simultaneously being considerably easier to manufacture, making it a formidable candidate for potential practical applications.

### Conclusions and Outlook

We present an innovative new method of producing thin, flexible, non-crystalline organic piezoelectric devices based on SAMs that show great potential for practical applications. The devices are simple, easy to manufacture due to their self-assembled nature that negates the need for electrical poling, and produce large voltage responses important for potential sensing applications.

FIGS. 5A, 5B and 5C show a flexible sealed PSAM device (CA12-NH2/DDT-PU) 10 of the present disclosure fabricated on gold-coated plastic substrates according to the present disclosure. FIG. 5A shows an image of device 10 being tested. FIG. 5B shows the current response of the flexible device 10. FIG. 5C shows the voltage response of flexible device 10. Current and voltage responses were measured due to (i) light finger taps while mounted, (ii) firm finger presses while mounted, and (iii) bending while held between three fingers. The device 10 produced nearly 4 nA of short-circuit current and 6 V of open-circuit voltage when subject to gentle bending motion.

Furthermore, their peptide nature makes them fully biocompatible and easily modifiable. Future work in tuning the sequence and functionalization of the amino acids as well as use of better dielectrics and more precise manufacturing methods holds the potential for large increases to the already outstanding voltage response of our PSAM devices.

Extended sequences of oligopeptide SAMs used in the piezoelectric materials, devices and/or methods of the present disclosure:
CA6: Cys-Ala-Ala-Ala-Ala-Ala-Ala
A6C: Ala-Ala-Ala-Ala-Ala-Ala-Cys
CA9: Cys-Ala-Ala-Ala-Ala-Ala-Ala-Ala-Ala-Ala
CA12: Cys-Ala-Ala-Ala-Ala-Ala-Ala-Ala-Ala-Ala-Ala-Ala-Ala
CA7: Cys-Ala-Ala-Ala-Ala-Ala-Ala-Ala
CA8: Cys-Ala-Ala-Ala-Ala-Ala-Ala-Ala-Ala
CA6F: Cys-Ala-Ala-Ala-Ala-Ala-Ala-Phe
CFA6: Cys-Phe-Ala-Ala-Ala-Ala-Ala-Ala
CA6Y: Cys-Ala-Ala-Ala-Ala-Ala-Ala-Tyr
CYA6: Cys-Tyr-Ala-Ala-Ala-Ala-Ala-Ala
CA6X: Cys-Ala-Ala-Ala-Ala-Ala-Ala-Xaa where Xaa is cyanophenylalanine (it is also sometimes abbreviated as Phe(4-CN) instead of Xaa).

Related U.S. Pat. No. 9,985,197 is incorporated by reference herein for all purposes.

### Methods

### Materials

Peptides CA₆ and A₆C were obtained from Sigma-Genosys. All other peptides were obtained from AnaSpec. Ethanol (200 proof) was obtained from Decon Labs. Acetonitrile (299.9%) and 1-dodecanethiol (≥98%) were obtained from Sigma-Aldrich. Petroleum ether (certified ACS) was obtained from Fisher Scientific. Liquid conformal polyurethane coating was obtained from MG Chemicals (Urethane Conformal Coating; Cat. No. 4223-55ML). Spray conformal polyurethane coating was obtained from Techspray (Fine-L-Kote UR Conformal Coating; Cat. No. 2104-12S). All chemicals were used as received. Ultrapure water (18.2 MΩ cm) was generated using a Millipore Synergy system.

### Device Preparation

Self-assembled monolayers (SAMs) were formed on the outer gold surface of 5 cm×5 cm custom designed and manufactured printed circuit boards (PCBs) (Where Labs/DirtyPCBs.com) with 3.5 cm×3.5 cm electroless nickel immersion gold (ENIG) finished copper pads. The PCBs were first cleaned by ultrasonicating them in ethanol for at least 30 min; rinsing sequentially with ethanol, water, and ethanol; and then drying them under a stream of nitrogen gas. Monolayers were formed by submerging the PCBs in a 0.5 mM-1 mM solution of the desired chemical or peptide for 48 h under ambient conditions to ensure uniformity. Solutions were prepared with either ethanol, water, acetonitrile, or a combination of the solvents depending on solubility; the solvent should not influence the resulting SAM.²⁰ After SAM formation, PCBs were removed from solution and washed using the same procedure as above before being wrapped in aluminum foil and stored in a vacuum desiccator. Wires were soldered onto the PCBs for testing.

In order to obtain consistent, reproducible contact between the PCBs, a commercial conformal polyurethane (PU) coating was applied to the surface of some PCBs using a spin coater (Chemat Technology Spin Coater KW-4A, 1 mL PU, 1000 rpm for 6 s increasing to 6000 rpm for 10 s). A thinner PU coating was obtained by mixing the PU with petroleum ether (50/50 v/v) before spin coating. The thickness of the PU coating was measured using calipers (0.040±0.004 mm normal coating; 0.023±0.003 mm thinner coating).

Sealed piezoelectric self-assembled monolayer (PSAM) devices were prepared by spraying one PCB with an aerosol can of commercial conformal PU, placing the other PCB and a 1 kg weight on top, and allowing the PU to dry. The PU thickness is 0.0.01 mm. A flexible sealed PSAM device was prepared by depositing a 10 nm titanium adhesion layer followed by a 100 nm gold layer on flexible Nunc Thermanox Plastic Coverslips (Thermo Scientific) using an electron beam evaporation system (Plassys Electron Beam Evaporator MEB550S); the flexible sealed PSAM device was then prepared similarly to the PCB sealed PSAM devices except that liquid PU was drop cast to form the dielectric layer (0.42 mm thickness). The flexible sealed PSAM device has an active area of 2.5 cm×2.5 cm.

### Device Testing and Characterization

Samples were removed from the desiccator at least 1 h prior to testing, as inconsistent results were obtained when testing was performed sooner. PSAM devices consisting of one PU coated PCB facing one uncoated, SAM functionalized PCB were tested in a quasi-static manner before the piezoelectric response was calculated. Similar to our previous work,²⁶ the PSAM device was positioned in a testing apparatus where force was applied using a stepper motor controlled threaded rod. A force sensor (Tekscan FlexiForce A201), with a poly(dimethylsiloxane) spacer on top, rested between the rod and the device under test. In order to reduce triboelectric charge generation, a preload force of '1 N was applied using the threaded rod before compressions of varying force (up to '6 N) were applied along the Z-axis at a rate of approximately 0.17 mm/s. Force and short-circuit current or open-circuit voltage measurements were recorded for 70 s and 90 s, respectively, using a Keithley 2614B SourceMeter. Each recorded measurement is the average of the values computed from three sequential, undisturbed test sequences, and each sample was tested at least five times with the PCBs of the PSAM device separated between measurements; sealed PSAM devices were not separated, but the preload force was removed and reapplied. As reported in our previous work, the system was tested on commercial ceramic piezoelectric materials to ensure accuracy.²⁶

The collected data are simply the applied force and measured current or voltage—both as a function of time. To calculate the piezoelectric charge constant (δ₃₃), force versus charge was plotted for each compression and the slope of the linear best fit was calculated using a robust linear regression (FIG. 6). A custom Python script was used to compute charge by integrating the current peaks over time;²⁶ we modified our previous script to optimize the peak finding sensitivity and to use a robust linear regression. The script identifies force peaks and subtracts off any baseline force; it then looks for the corresponding current peak and integrates it to calculate the resultant charge during the period of increasing applied force. The piezoelectric voltage constant _{(γ33)} was calculated in a similar manner except that, after the force and voltage peaks were identified, voltage was converted to induced electric field by dividing by sample thickness and force was converted to external stress by dividing by electrode area (see FIG. 7 and minimum working example Python script below).

### Ab Initio Molecular Dynamis Simulations

We used the software package CP2K,^{27,28} based on the Born-Oppenheimer approach, to perform ab initio molecular dynamics (AIMD) simulations of samples containing carboxylate-terminated peptide CA₆ or amide-terminated peptide CA₆-NH₂ solvated in liquid water; both were under the action of static and homogeneous electric fields applied along a given direction (corresponding to the Z-axis). The implementation of an external field in numerical codes based on Density Functional Theory (DFT) can be achieved by exploiting the Modern Theory of Polarization and Berry's phases₂₉₋₃₁ (see, e.g., Ref.³²). The CA₆-containing numerical sample was composed of one CA₆ peptide solvated by 253 H₂O molecules (i.e., 833 atoms) arranged in a cubic cell with edge equal to 20.4 Å, so as to reproduce the liquid water experimental density of 1.00 g/cm³ at room temperature. Similarly, the CA₆-NH₂-containing numerical sample was composed of one CA₆-NH₂ peptide solvated by 253 H₂O molecules (i.e., 835 atoms) arranged in a cubic cell with edge equal to 20.4 Å. As usual, in order to minimize nonphysical surface effects, all structures were replicated in space by employing periodic boundary conditions. The intensity of the electric field was gradually increased with a step increment of 0.5 V/nm from zero up to a maximum of 1.0 V/nm. In the zero-field cases, we performed dynamics of 50 ps for each investigated sample whereas, for each other value of the field intensity, we ran dynamics of 20 ps, thus accumulating a global simulation time equal to 180 ps where a time-step of 0.5 fs was chosen. Additional tests employing different atomistic configurations of the initial structures and/or assigning diverse initial atomic velocities were executed in order to exclude biases stemming from specific initial molecular arrangements.

Wavefunctions of the atomic species were expanded in the triple-zeta valence plus polarization (TZVP) basis set with Goedecker-Teter-Hutter pseudopotentials using the GPW method.³³ A plane-wave cutoff of 400 Ry was imposed. Exchange and correlation (XC) effects were treated with the Becke-Lee-Yang-Parr (BLYP)³⁴ density functional. Moreover, in order to take into account dispersion interactions, we employed the dispersion-corrected version of BLYP (i.e., BLYP-D3).^{35,36} The adoption of the BLYP-D3 functional has been dictated by the widespread evidence that such a functional, when dispersion corrections are taken into account, offers one of the best adherences with the experimental results related to water among the standard GGA functionals.^{37,38} It is well-known that neglecting dispersion corrections leads to a severely over-structured liquid (see, e.g., Ref.³⁹ and references therein). In order to counteract the overstructuring of intermolecular interactions typically induced by GGA XC functionals, all simulations were executed at a temperature of 350 K. The dynamics of nuclei were simulated classically within a constant number, volume, and temperature (NVT) ensemble using the Verlet algorithm whereas the canonical sampling was executed by employing a canonical-sampling-through-velocity-rescaling thermostat⁴⁰ set with a time constant equal to 10 fs.

### Supporting Information

### Intrinsically Polar Piezoelectric Self-Assembled Oligopeptide Monolayers

### Anova

Analysis of Variance (ANOVA) was used to determine if different effects have statistical significance. The ANOVA calculations were performed using LibreOffice Calc (v. 6.4.5.2) software, and the results are presented in Tables S1-S12.

TABLE S1
The data do not show a statistically significant
effect between tests of the piezoelectric charge
constant _{(d33)} using different DDT-PU coated PCBs.

| Group | Count | Sum | Mean | Variance | |
|---|---|---|---|---|---|
| d₃₃ DDT-PU PCB 1 | 16 | 130.04 | 8.13 | 16.86 | |
| d₃₃ DDT-PU PCB 2 | 19 | 147.41 | 7.76 | 13.06 | |
| d₃₃ DDT-PU PCB 3 | 18 | 165.79 | 9.21 | 21.68 | |
| Source of Variation | SS | df | MS | F | P-value |
| Between Groups | 20.76 | 2 | 10.38 | 0.61 | 0.55 |
| Within Groups | 856.62 | 50 | 17.13 | | |

TABLE S2
The data do not show a statistically significant effect between tests of
the piezoelectric charge constant _{(d33)} using different PU coated PCBs.

| Group | Count | Sum | Mean | Variance | |
|---|---|---|---|---|---|
| d₃₃ PU PCB 1 | 15 | 58.76 | 3.92 | 4.59 | |
| d₃₃ PU PCB 2 | 13 | 57.01 | 4.39 | 6.19 | |
| Source of Variation | SS | df | MS | F | P-value |
| Between Groups | 1.25 | 1 | 1.53 | 0.29 | 0.60 |
| Within Groups | 138.46 | 26 | 5.33 | | |

TABLE S3
The data show a statistically significant effect between tests of the
piezoelectric charge constant _{(d33)} using different thin PU coated PCBs.

| Group | Count | Sum | Mean | Variance | |
|---|---|---|---|---|---|
| d₃₃ Thin PU PCB 1 | 14 | 116.61 | 8.33 | 14.96 | |
| d₃₃ Thin PU PCB 2 | 14 | 55.09 | 3.94 | 2.65 | |
| d₃₃ Thin PU PCB 3 | 4 | 34.03 | 8.51 | 2.52 | |
| Source of Variation | SS | df | MS | F | P-value |
| Between Groups | 154.91 | 2 | 77.45 | 9.50 | 0.000 67 |
| Within Groups | 236.54 | 29 | 8.17 | | |

TABLE S4
The data appear to show a statistically significant effect (P-value < 0.05)
between tests of the piezoelectric charge constant _{(d33)} using
carboxylate-terminated and amide-terminated peptides.

| Group | Count | Sum | Mean | Variance | |
|---|---|---|---|---|---|
| d₃₃ Carboxylate-Terminated Peptides | 61 | 369.62 | 6.06 | 11.07 | |
| d₃₃ Amide-Terminated Peptides | 52 | 395.13 | 7.60 | 19.82 | |
| Source of Variation | SS | df | MS | F | P-value |
| Between Groups | 66.52 | 1 | 66.52 | 4.41 | 0.038 |
| Within Groups | 1675.00 | 111 | 15.09 | | |

TABLE S5
The data do not show a statistically significant effect
between tests of the piezoelectric charge constant _{(d33)}
using different length carboxylate-terminated peptides.

| Group | Count | Sum | Mean | Variance | |
|---|---|---|---|---|---|
| d₃₃ CA₆ | 14 | 70.78 | 5.06 | 7.44 | |
| d₃₃ A₆C | 14 | 80.03 | 5.72 | 5.91 | |
| d₃₃ CA₉ | 16 | 104.47 | 6.53 | 16.34 | |
| d₃₃ CA₁₂ | 16 | 106.44 | 6.65 | 14.44 | |
| Source of Variation | SS | df | MS | F | P-value |
| Between Groups | 24.85 | 3 | 8.28 | 0.73 | 0.54 |
| Within Groups | 635.19 | 56 | 11.34 | | |

TABLE S6
The data do not show a statistically significant effect
between tests of the piezoelectric charge constant _{(d33)}
using different length amide-terminated peptides.

| Group | Count | Sum | Mean | Variance | |
|---|---|---|---|---|---|
| d₃₃ CA₆-NH₂ | 14 | 102.39 | 7.31 | 17.44 | |
| d₃₃ CA₉-NH₂ | 18 | 135.32 | 7.52 | 18.75 | |
| d₃₃ CA₁₂-NH₂ | 14 | 87.76 | 6.27 | 9.06 | |
| Source of | | | | | |
| Variation | SS | df | MS | F | P-value |
| Between | 13.43 | 2 | 6.71 | 0.44 | 0.65 |
| Groups | | | | | |
| Within | 663.22 | 43 | 15.42 | | |
| Groups | | | | | |

TABLE S7
The data show a statistically significant
effect between tests of the piezoelectric
charge constant _{(d33)} using unfunctionalized
and DDT functionalized PU coated PCBs.

| Group | Count | Sum | Mean | Variance | |
|---|---|---|---|---|---|
| d₃₃ DDT-PU | 46 | 365.69 | 7.95 | 12.90 | |
| d₃₃ PU | 28 | 115.77 | 4.13 | 5.18 | |
| Source of Variation | SS | df | MS | F | P-value |
| Between Groups | 253.32 | 1 | 253.32 | 25.32 | 0.000 003 4 |
| Within Groups | 720.31 | 72 | 10.00 | | |

TABLE S8
The data show a statistically significant
effect between tests of the piezoelectric charge
constant _{(d33)} using PCBs coated with normal
thickness PU and thinner thickness PU.

| Group | Count | Sum | Mean | Variance | |
|---|---|---|---|---|---|
| d₃₃ Normal PU | 28 | 115.77 | 4.13 | 5.18 | |
| d₃₃ Thin PU | 32 | 205.73 | 6.43 | 12.63 | |
| Source of Variation | SS | df | MS | F | P-value |
| Between Groups | 78.61 | 1 | 78.61 | 8.58 | 0.0049 |
| Within Groups | 531.44 | 58 | 9.16 | | |

TABLE S9
The data show a statistically significant effect
between tests of the piezoelectric voltage
constant _{(g33)} using different DDT-PU coated PCBs.

| Group | Count | Sum | Mean | Variance | |
|---|---|---|---|---|---|
| g₃₃ DDT-PU PCB 1 | 14 | 11 714 | 837 | 99 346 | |
| g₃₃ DDT-PU PCB 2 | 14 | 6396 | 457 | 35 136 | |
| g₃₃ DDT-PU PCB 3 | 16 | 7603 | 475 | 31 404 | |
| Source of Variation | SS | df | MS | F | P-value |
| Between Groups | 1 309 918 | 2 | 654 959 | 12.10 | 0.000 074 |
| Within Groups | 2 219 335 | 41 | 54 130 | | |

TABLE S10
The data do not show a statistically significant effect
between tests of the piezoelectric voltage
constant _{(g33)} using different PU coated PCBs.

| Group | Count | Sum | Mean | Variance | |
|---|---|---|---|---|---|
| g₃₃ PU PCB 1 | 14 | 6566 | 469 | 52 126 | |
| g₃₃ PU PCB 2 | 14 | 6543 | 467 | 58 555 | |
| Source of Variation | SS | df | MS | F | P-value |
| Between Groups | 18.66 | 1 | 18.66 | 0.000 34 | 0.99 |
| Within Groups | 1 438 852 | 26 | 55 340 | | |

TABLE S11
The data show a statistically significant effect
between tests of the piezoelectric voltage
constant _{(g33)} using different thin PU coated PCBs.

| Group | Count | Sum | Mean | Variance | |
|---|---|---|---|---|---|
| g₃₃ Thin PU PCB 1 | 16 | 33 812 | 2113 | 1 742 123 | |
| g₃₃ Thin PU PCB 2 | 16 | 16 132 | 1008 | 160 542 | |
| g₃₃ Thin PU PCB 3 | 8 | 7671 | 959 | 416 999 | |
| Source of Variation | SS | df | MS | F | P-value |
| Between Groups | 12 087 411 | 2 | 6 043 705 | 7.11 | 0.0024 |
| Within Groups | 31 458 975 | 37 | 850 243 | | |

TABLE S12
The data show a statistically significant effect between tests of the
piezoelectric voltage constant _{(γ33)} using PCBs coated with
normal thickness PU and thinner thickness PU.

| Group | Count | Sum | Mean | Variance | |
|---|---|---|---|---|---|
| γ₃₃ Normal PU | 28 | 13 110 | 468 | 53 292 | |
| γ₃₃ Thin PU | 40 | 57 615 | 1440 | 1 116 574 | |
| Source of Variation | SS | df | MS | F | P-value |
| Between Groups | 15 566 850 | 1 | 15 566 850 | 22.84 | 0.000 010 |
| Within Groups | 44 985 256 | 66 | 681 595 | | |

FIGS. 6A and 6B illustrates the process by which the piezoelectric charge constant_{(δ33)} is obtained according to the present disclosure. FIG. 6A shows the simultaneous measurement of force and short-circuit current over time. The gold shading represents the time over which the current is integrated to calculate charge; the absolute value of the charge is then used. FIG. 6B shows a charge-force plot for a CA₆-NH₂/DDT-PU PSAM device of the present disclosure showing a _{δ33} of 9.93 pC/N.

FIGS. 7A and 7B illustrate the process by which the piezoelectric voltage constant _{(γ33)} is obtained. FIG. 7A shows simultaneous measurement of force and open-circuit voltage over time; the baseline of the measured voltage is first corrected for measurement drift. The dashed gold line shows corresponding force and voltage peaks. FIG. 7B shows the induced electric field-external stress plot for a CA12-NH₂/thin-PU PSAM device of the present disclosure showing a γ₃₃ of 1565 mVm/N. Induced electric field is calculated by dividing voltage by sample thickness; external stress is calculated by dividing applied force by electrode area.

FIG. 8 shows piezoelectric charge constant _{(δ33)} values for 1-dodecanethiol (DDT) control PSAM devices of the present disclosure. Control values are less than 3 pC/N. Error bars represent standard error across multiple samples.

FIG. 9 shows that piezoelectric voltage constant _{(γ33)} values for 1-dodecanethiol (DDT) control PSAM devices of the present disclosure. Control values for normal thickness PU devices are less than 300 mVm/N. Error bars represent standard error across multiple samples.

FIGS. 10A and 10B show that samples of the present disclosure retain piezoelectric response over several months of storage in a vacuum desiccator wherein FIG. 10 A shows a response grouped by sample and FIG. 10B shows a response as a function of storage time. Error bars represent standard error across multiple tests.

FIG. 11 shows the piezoelectric voltage constants _{(γ33)} of sealed PSAM devices. The _{γ33} of sealed PSAM devices is similar to that of other samples despite the thinner PU layer; the _{δ33} is much lower (not shown); and the stability is much better. Error bars represent standard error across multiple tests.

FIG. 12 shows that sealed PSAM devices retain response over 18 d and approximately 900 test cycles under ambient conditions. The increase in response over time is due, in part, to the gradual decrease of preload force due to the nature of the testing setup. Data were excluded around day 11 due to HVAC instability. Error bars represent standard error is the slope of the robust linear regression for each individual test.

### Supplementary Note: Computational Details and Discussion

The piezoelectric response of carboxylate/amide-terminated peptides is ultimately dependent on the strength of the H-bonds constituting their own a-helices, whose lengths are defined in FIG. 13.

FIG. 13 shows atomistic visualization of the carboxylate-terminated peptide CA₆ in liquid water from room-temperature ab initio molecular dynamics simulations. In the inset, a magnification displaying the definition of the four crucial interatomic distances (d₁, d₂, d₃, d₄) determining the α-helix structure is shown. Equivalent definitions also hold for the amide-terminated peptide CA₆-NH₂ structure. Red, grey, yellow, blue, and white coloring refer to oxygen, carbon, sulfur, nitrogen, and hydrogen atoms, respectively.

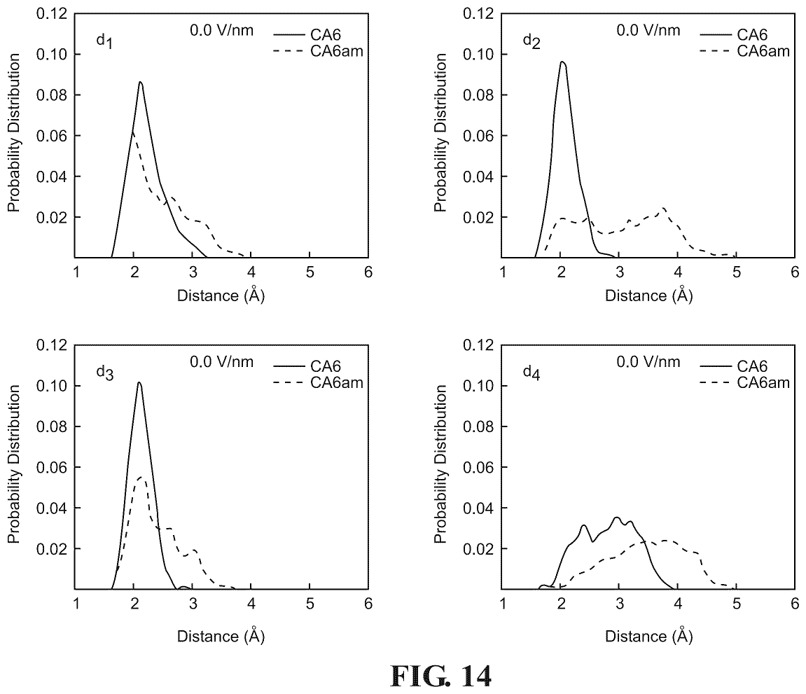

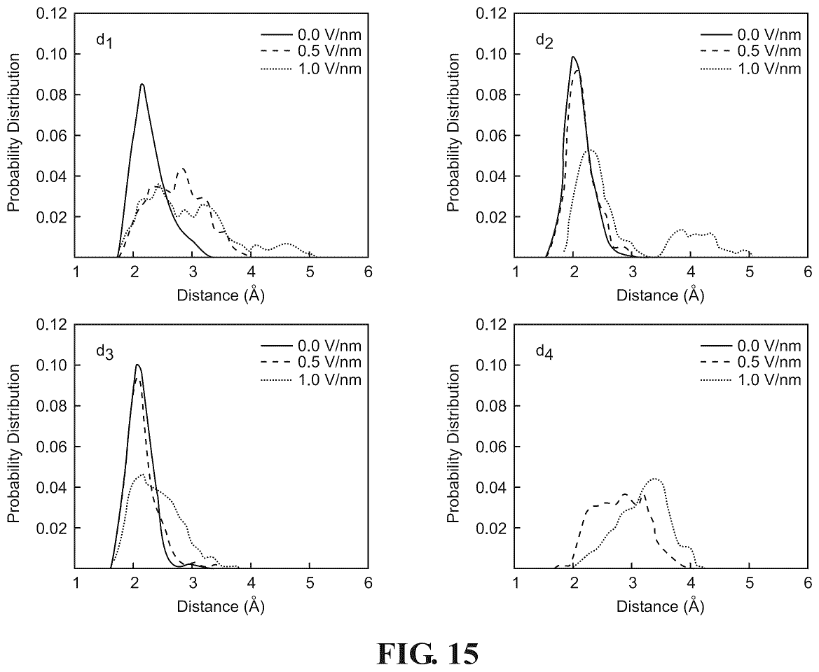

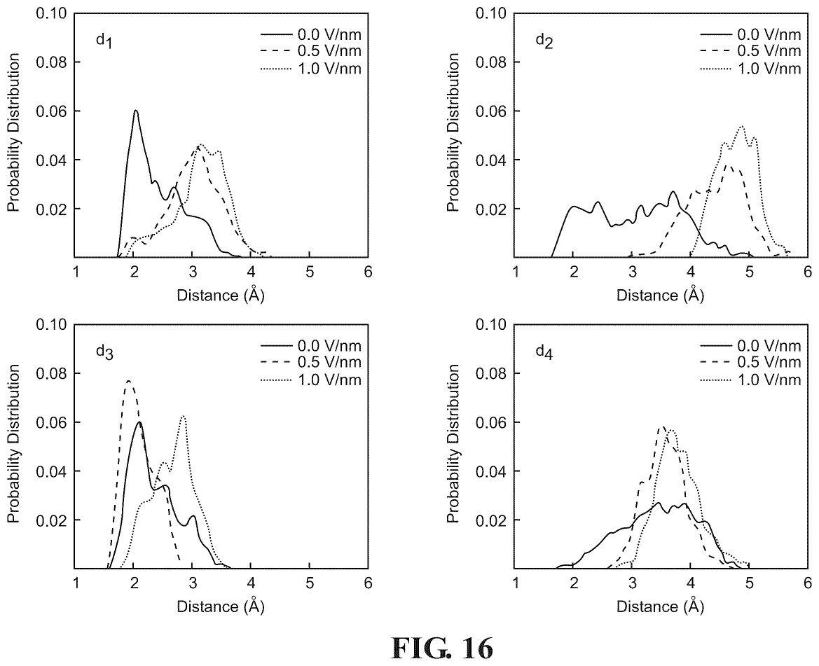

In order to atomistically monitor the behavior of carboxylate-terminated peptides CA₆ and amide-terminated peptides CA₆-NH₂, a series of ab initio molecular dynamics (AIMD) simulations at room conditions and under the effect of different field intensities was executed. As shown in FIG. 14, in the zero-field regime and at room temperature, the four NH · · · O internal distances of the CA₆ species exhibit values statistically falling within the range of typical strong-to-moderate H-bonds (i.e., <[1.7□3.2] Å), with the exception of d₄ which also probes longer distances. This latter represents the weakest interatomic bond-among those defining the α-helix-since it shares the acceptor oxygen atom with the bond defined as d₃ (FIG. 13). This way, the α-helix structure of CA₆ is essentially determined by the H-bonds identified by d₁, d₂, and d₃. On the other hand, the probability distributions characterizing all four internal H-bonds of the amide-terminated peptide CA₆-NH₂ exhibit broader distributions than their counterparts in the CA₆ species, indicating that amide-terminated α-helices are less rigid than the carboxylate-terminated ones. In fact, both d₁ and d₃ distributions are slightly broader in CA₆-NH₂ with respect to their homologues in CA₆, as shown in FIG. 14. Moreover, the weakest H-bond of the CA₆ peptide, identified by d₄, develops into very feeble interatomic interactions, exhibiting distances beyond the typical lengths of very weak H-bonds (i.e., r^{t} . . . 4 Å). Nevertheless, the most prominent difference is recorded for the H-bond defined as d₂. Whereas in the CA₆ peptide structure such a bond exhibits lengths which are ascribable to H-bonds with a predominantly covalent character (i.e., r^{t} . . . 2 Å), in the amide-terminated CA₆-NH₂ species the same bond shows lengths typical of very weak H-bonds or even being purely electrostatic in nature. Those microscopic aspects are crucial not only in interpreting the results concerning the electric-field-induced effects on the α-helices of the peptides shown in FIGS. 15 and 16, but also in the understanding of the larger piezoelectric response of the amide-terminated peptides with respect to their carboxylate-terminated counterparts emerging from experiments.

A series of analyses on the crucial H-bonds defining the α-helix was executed. As shown in FIG. 15, the application of electric field strengths on the order of 0.5 V/nm perturbs the internal H-bonds of the CA₆ structure. In fact, one of the four bonds characterizing the α-helix (i.e., d₁) starts exploring larger distances. However, all the remaining probability distributions associated with the other H-bonds are not significantly altered by the field action, as shown in FIG. 15. Such a finding highlights, once again, the robustness of the structure of the carboxylate-terminated peptide CA₆. On the other hand, a field intensity of 1.0 V/nm is able to almost completely break the α-helix structure, leaving partially intact only the H-bond identified as d₃ and the weakest (and very weak) intermolecular bond defined as d₄, as shown in FIG. 15.

As previously mentioned, in the zero-field regime the structure of the amide-terminated peptide CA₆-NH₂ is less rigid than its own carboxylate-terminated counterpart. The weaker internal H-bonds constituting the α-helix render the CA₆-NH₂ structure more sensitive to the application of external electrostatic potential gradients. In fact, a field strength of 0.5 V/nm is already able to largely affect most of the lengths of the bonds under investigation, as shown in FIG. 16.

FIG. 14 shows probability distributions of the lengths of the four H-bonds characterizing the a-helix structure of the carboxylate-terminated peptide (CA₆; solid blue curves) and the amide-terminated peptide (CA₆αμ; dashed yellow curves), as determined by ab initio molecular dynamics simulations in the zero-field regime (i.e., E=0.0 V/nm). For the distances definition see FIG. 13.

FIG. 15 shows probability distributions of the lengths of the four H-bonds characterizing the α-helix structure of the carboxylate-terminated peptide CA₆ in the zero-field regime (solid black curves) and at field strengths of 0.5 V/nm (dashed blue curves) and 1.0 V/nm (dotted red curves), as determined by ab initio molecular dynamics simulations. For the distances definition. See FIG. 13.

FIG. 16 shows probability distributions of the lengths of the four H-bonds characterizing the α-helix structure of the amide-terminated peptide CA₆-NH₂ in the zero-field regime (solid black curves) and at field strengths of 0.5 V/nm (dashed blue curves) and 1.0 V/nm (dotted red curves), as determined by ab initio molecular dynamics simulations. For the distances definition see FIG. 13.

### Acknowledgments

The authors thank Zheni Georgieva for assistance with spin coating and Nathaniel Miller for assistance in preparing the flexible substrates. The authors acknowledge the University of Pittsburgh for financial support. Software used in this work includes, in part, Avogadro,⁴¹ CP2K,⁴² Matplotlib,⁴³ NumPy,⁴⁴ pandas,⁴⁵ pySerial, SciPy,⁴⁶ Statsmodels,⁴⁷ and Python-VXI11.

### REFERENCES

(1) Tressler, J. F.; Alkoy, S.; Newnham, R. E. Piezoelectric Sensors and Sensor Materials. J. Electroceram. 1998, 2, 257-272.
(2) Briscoe, J.; Dunn, S. Piezoelectric Nanogenerators: A Review of Nanostructured Piezoelectric Energy Harvesters. Nano Energy 2015, 14, 15-29.
(3) Uchino, K. Piezoelectric Actuators 2006: Expansion from IT/Robotics to Ecological/Energy Applications. J. Electroceram. 2007, 20, 301-311.
(4) Ramadan, K. S.; Sameoto, D.; Evoy, S. A Review of Piezoelectric Polymers as Functional Materials for Electromechanical Transducers. Smart Mater. Struct. 2014, 23, 033001.
(5) Kim, D.; Han, S. A.; Kim, J. H.; Lee, J.-H.; Kim, S.-W.; Lee, S.-W. Biomolecular Piezoelectric Materials: From Amino Acids to Living Tissues. Adv. Mater. (Weinheim, Ger.) 2020, 32, 1906989.
(6) Dagdeviren, C.; Joe, P.; Tuzman, O. L.; Park, K.-I.; Lee, K. J.; Shi, Y.; Huang, Y.; Rogers, J. A. Recent Progress in Flexible and Stretchable Piezoelectric Devices for Mechanical Energy Harvesting, Sensing and Actuation. Extreme Mech. Lett. 2016, 9, 269-281.
(7) Li, H.; Tian, C.; Deng, Z. D. Energy Harvesting from Low Frequency Applications Using Piezoelectric Materials. Appl. Phys. Rev. 2014, 1, 041301.
(8) Stetsovych, O.; Mutombo, P.; Švec, M.; Šámal, M.; Nejedlt, J.; Císařová, I.; Vázquez, H.; Moro-Lagares, M.; Berger, J.; Vacek, J.; Stará, I. G.; Start, I.; Jelínek, P. Large Converse Piezoelectric Effect Measured on a Single Molecule on a Metallic Surface. J. Am. Chem. Soc. 2018, 140, 940-946.
(9) Lee, J.-H.; Heo, K.; Schulz-Schönhagen, K.; Lee, J. H.; Desai, M. S.; Jin, H.-E.; Lee, S.-W. Diphenylalanine Peptide Nanotube Energy Harvesters. ACS Nano 2018, 12, 8138-8144.
(10) Hosseini, E. S.; Manjakkal, L.; Shakthivel, D.; Dahiya, R. Glycine-Chitosan-Based Flexible Biodegradable Piezoelectric Pressure Sensor. ACS Appl. Mater. Interfaces 2020, 12, 9008-9016.
(11) Guerin, S.; O'Donnell, J.; Haq, E. U.; Mckeown, C.; Silien, C.; Rhen, F. M. F.; Soulimane, T.; Tofail, S. A. M.; Thompson, D. Racemic Amino Acid Piezoelectric Transducer. Phys. Rev. Lett. 2019, 122, 047701.
(12) Lee, B. Y.; Zhang, J.; Zueger, C.; Chung, W.-J.; Yoo, S. Y.; Wang, E.; Meyer, J.; Ramesh, R.; Lee, S.-W. Virus-Based Piezoelectric Energy Generation. Nat. Nanotechnol. 2012, 7, 351-356.
(13) Akdogan, E. K.; Allahverdi, M.; Safari, A. Piezoelectric Composites for Sensor and Actuator Applications. IEEE Trans. Ultrason. Ferroelectr. Freq. Control 2005, 52, 746-775.
(14) Safari, A.; Akdogan, E. K. Rapid Prototyping of Novel Piezoelectric Composites. Ferroelectrics 2006, 331, 153-179.
(15) Guerin, S.; Stapleton, A.; Chovan, D.; Mouras, R.; Gleeson, M.; Mckeown, C.; Noor, M. R.; Silien, C.; Rhen, F. M. F.; Kholkin, A. L.; Liu, N.; Soulimane, T.; Tofail, S. A. M.; Thompson, D. Control of Piezoelectricity in Amino Acids by Supramolecular Packing. Nature Mat. 2017, 17, 180-186.
(16) Chen, X.; Ware, H. O. T.; Baker, E.; Chu, W.; Hu, J.; Sun, C. The Development of an All-polymer-based Piezoelectric Photocurable Resin for Additive Manufacturing. Procedia CIRP 2017, 65, 157-162, 3rd CIRP Conference on BioManufacturing.
(17) IEEE Standard on Piezoelectricity. ANSI/IEEE Std 176-1987 1988, 1-66.
(18) Quan, X.; Madura, J. D.; Hutchison, G. R. Self-Assembled Monolayer Piezoelectrics: Electric-Field Driven Conformational Changes. 2017.
(19) Miller, N. C.; Grimm, H. M.; Horne, W. S.; Hutchison, G. R. Accurate Electromechanical Characterization of Soft Molecular Monolayers Using Piezo Force Microscopy. Nanoscale Adv. 2019, 1, 4834-4843.
(20) Love, J. C.; Estroff, L. A.; Kriebel, J. K.; Nuzzo, R. G.; Whitesides, G. M. Self-Assembled Monolayers of Thiolates on Metals as a Form of Nanotechnology. Chem. Rev. 2005, 105, 1103-1170.
(21) Quan, X.; Marvin, C. W.; Seebald, L.; Hutchison, G. R. Single-Molecule Piezoelectric Deformation: Rational Design from First-Principles Calculations. J. Phys. Chem. C 2013, 117, 16783-16790.
(22) Marvin, C. W.; Grimm, H. M.; Miller, N. C.; Horne, W. S.; Hutchison, G. R. Interplay among Sequence, Folding Propensity, and Bio-Piezoelectric Response in Short Peptides and Peptoids. J. Phys. Chem. B 2017, 121, 10269-10275.
(23) Yang, M.-M.; Luo, Z.-D.; Mi, Z.; Zhao, J.; E, S. P.; Alexe, M. Piezoelectric and Pyroelectric Effects Induced by Interface Polar Symmetry. Nature 2020, 584, 377-381.
(24) Chen, H. D.; Udayakumar, K. R.; Cross, L. E.; Bernstein, J. J.; Niles, L. C. Dielectric, Ferroelectric, and Piezoelectric Properties of Lead Zirconate Titanate Thick Films on Silicon Substrates. J. Appl. Phys. (Melville, NY, U. S.) 1995, 77, 3349-3353.
(25) Goh, W.; Yao, K.; Ong, C. Effects of Microstructure on the Properties of Ferroelectric Lead Zirconate Titanate (PZT) Thin Films. Appl. Phys. A: Mater. Sci. Process. 2005, 81, 1089-1093.
(26) Petroff, C. A.; Bina, T. F.; Hutchison, G. R. Highly Tunable Molecularly Doped Flexible Poly(dimethylsiloxane) Foam Piezoelectric Energy Harvesters. ACS Appl. Energy Mater. 2019, 2, 6484-6489.
(27) Hutter, J.; Iannuzzi, M.; Schiffmann, F.; Vande Vondele, J. CP2K: Atomistic Simulations of Condensed Matter Systems. Wiley Interdiscip. Rev.: Comput. Mol. Sci. 2014, 4, 15-25.
(28) Vande Vondele, J.; Krack, M.; Mohamed, F.; Parrinello, M.; Chassaing, T.; Hutter, J. QUICKSTEP: Fast and Accurate Density Functional Calculations Using a Mixed Gaussian and Plane Waves Approach. Comput. Phys. Commun. 2005, 167, 103-128.
(29) King-Smith, R. D.; Vanderbilt, D. Theory of Polarization of Crystalline Solids. Phys. Rev. B 1993, 47, 1651-1654.
(30) Resta, R. Macroscopic Polarization in Crystalline Dielectrics: The Geometric Phase Approach. Rev. Mod. Phys. 1994, 66, 899-915.
(31) Berry, M. V. Quantal Phase Factors Accompanying Adiabatic Changes. Proc. R. Soc. London, Ser. A 1984, 392, 45-57.
(32) Umari, P.; Pasquarello, A. Ab Initio Molecular Dynamics in a Finite Homogeneous Electric Field. Phys. Rev. Lett. 2002, 89, 157602.
(33) Krack, M. Pseudopotentials for H to Kr Optimized for Gradient-Corrected Exchange-Correlation Functionals. Theor. Chem. Acc. 2005, 114, 145-152.
(34) Becke, A. D. Density-Functional Exchange-Energy Approximation with Correct Asymptotic Behavior. Phys. Rev. A 1988, 38, 3098-3100.
(35) Grimme, S.; Antony, J.; Ehrlich, S.; Krieg, H. A Consistent and Accurate ab Initio Parametrization of Density Functional Dispersion Correction (DFT-D) for the 94 Elements H-Pu. J. Chem. Phys. 2010, 132, 154104.
(36) Grimme, S.; Ehrlich, S.; Goerigk, L. Effect of the Damping Function in Dispersion Corrected Density Functional Theory. J. Comput. Chem. 2011, 32, 1456-1465.
(37) Lin, I.-C.; Seitsonen, A. P.; Tavernelli, I.; Rothlisberger, U. Structure and Dynamics of Liquid Water from ab Initio Molecular Dynamics—Comparison of BLYP, PBE, and revPBE Density Functionals with and without van der Waals Corrections. J. Chem. Theory Comput. 2012, 8, 3902-3910.
(38) Bankura, A.; Karmakar, A.; Carnevale, V.; Chandra, A.; Klein, M. L. Structure, Dynamics, and Spectral Diffusion of Water from First-Principles Molecular Dynamics. TJ. Phys. Chem. C 2014, 118, 29401-29411.
(39) Gillan, M. J.; Alfè, D.; Michaelides, A. Perspective: How Good is DFT for Water? J. Chem. Phys. 2016, 144, 130901.
(40) Bussi, G.; Donadio, D.; Parrinello, M. Canonical Sampling Through Velocity Rescaling. J. Chem. Phys. 2007, 126, 014101.
(41) Hanwell, M. D.; Curtis, D. E.; Lonie, D. C.; Vandermeersch, T.; Zurek, E.; Hutchison, G. R. Avogadro: An Advanced Semantic Chemical Editor, Visualization, and Analysis Platform. J. Cheminf. 2012, 4.
(42) Kühne, T. D. et al. CP2K: An Electronic Structure and Molecular Dynamics Software Package-Quickstep: Efficient and Accurate Electronic Structure Calculations. J. Chem. Phys. 2020, 152, 194103.
(43) Hunter, J. D. Matplotlib: A 2D Graphics Environment. Comput. Sci. Eng. 2007, 9, 90-95.
(44) Van Der Walt, S.; Colbert, S. C.; Varoquaux, G. The NumPy Array: A Structure for Efficient Numerical Computation. Comput. Sci. Eng. 2011, 13, 22.
(45) Mckinney, W. Data Structures for Statistical Computing in Python. Proceedings of the 9th Python in Science Conference. 2010; pp 56-61.
(46) Virtanen, P. et al. SciPy 1.0: Fundamental Algorithms for Scientific Computing in Python. Nat. Methods 2020, 17, 261-272.
(47) Seabold, S.; Perktold, J. Statsmodels: Econometric and Statistical Modeling with Python. Proceedings of the 9th Python in Science Conference. 2010; pp 92-96.

What is claimed is:

1. A flexible biocompatible material, comprising:
an oligopeptide self-assembled monolayer disposed/deposited on a first electrode; and
a dielectric layer disposed/deposited over and/or attached to the oligopeptide self-assembled monolayer and the first electrode.

2. A flexible biocompatible material, comprising:
an oligopeptide self-assembled monolayer disposed/deposited on a first printed circuit board; and
a dielectric layer disposed/deposited over and/or attached to the oligopeptide self-assembled monolayer and the first printed circuit board.

3. The flexible biocompatible material of claim 1, wherein the dielectric layer comprises polyurethane, a polyurethane film or other suitable polymer or polymer film or a non-polymer material.

4. The flexible biocompatible material of claim 1, wherein the dielectric layer has a thickness of about 40 μm.

5. The flexible biocompatible material of claim 1, wherein the dielectric layer has a thickness of about 23 μm.

6. The flexible biocompatible material of claim 1, wherein the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

7. The flexible biocompatible material of claim 1, wherein the oligopeptide self-assembled monolayer is carboxylate terminated or amide terminated.

8. A piezoelectric self-assembling monolayer device, comprising:
a flexible biocompatible material of claim 1 having a second electrode or second printed circuit board sealed over or on top of the dielectric layer.

9. The piezoelectric self-assembling monolayer device of claim 8, wherein the dielectric layer is used to adhere or attach the second electrode or second printed circuit board to the oligopeptide self-assembled monolayer and the first electrode or first printed circuit board and to seal the device from the atmosphere.

10. The piezoelectric self-assembling monolayer device of claim 8, wherein the dielectric layer comprises polyurethane, a polyurethane film or other suitable polymer or polymer film or a non-polymer material.

11. A flexible sealed piezoelectric device, comprising:
a first electrode layer or a first printed circuit board layer adhered to a flexible substrate by an adhesion layer; wherein the adhesion layer is disposed/deposited between the flexible substrate and the first electrode layer or the first printed circuit board layer;
an oligopeptide self-assembled monolayer disposed/deposited on the first electrode layer or first printed circuit board layer; and
a second electrode layer or second printed circuit board layer adhered to and sealed to the oligopeptide self-assembled monolayer and the first electrode layer or the first printed circuit board layer by a dielectric layer disposed/deposited over and attached to the oligopeptide self-assembled monolayer and the first electrode layer or the first printed circuit board layer.

12. The flexible sealed piezoelectric device of claim 11, wherein the flexible substrate comprises a polymer or plastic coverslip such as a Nunc Thermanox Plastic Coverslip available from Thermo Scientific.

13. The flexible sealed piezoelectric device of claim 11, wherein the adhesion layer comprises titanium.

14. The flexible sealed piezoelectric device of claim 11, wherein the adhesion layer has a thickness of about 10 nm.

15. The flexible sealed piezoelectric device of claim 11, wherein the first electrode layer or first printed circuit board layer comprises gold.

16. The flexible sealed piezoelectric device of claim 11, wherein the first electrode layer or the first printed circuit board layer has a thickness of about 100 nm.

17. The flexible sealed piezoelectric device of claim 11, wherein the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

18. The flexible sealed piezoelectric device of claim 11, wherein the dielectric layer comprises polyurethane, a polyurethane film or other suitable polymer or polymer film or a non-polymer material.

19. The flexible sealed piezoelectric device of claim 11, wherein the oligopeptide self-assembled monolayer is carboxylate terminated or amide terminated.

20. A force/touch sensor comprising:
an oligopeptide self-assembled monolayer disposed/deposited on an electrode or a printed circuit board; and
a dielectric layer disposed/deposited over the oligopeptide self-assembled monolayer and the electrode or printed circuit board.

21. The force/touch sensor of claim 20 wherein the dielectric layer comprises polyurethane, a polyurethane film or other suitable polymer or polymer film or a non-polymer material.

22. The force/touch sensor of claim 20, wherein the dielectric layer has a thickness of about 40 μm.

23. The force/touch sensor of claim 20, wherein the dielectric layer has a thickness of about 23 μm.

24. The force/touch sensor of claim 20, wherein the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

25. The force/touch sensor of claim 20, wherein the oligopeptide self-assembled monolayer is carboxylate terminated or amide terminated.

26. A method for making a flexible sealed piezoelectric device/sensor, comprising:
depositing an adhesion layer on a flexible substrate;
depositing a first electrode layer or printed circuit board layer on the adhesion layer;
forming an oligopeptide self-assembled monolayer on the first electrode layer or first printed circuit board layer;
coating the oligopeptide self-assembled monolayer with a liquid solution of dielectric material;
placing a second electrode layer or a second printed circuit board layer onto the liquid solution of dielectric material; and
compressing the second electrode layer or second printed circuit board layer against the liquid solution of dielectric material until the liquid solution of dielectric material dries or cures.

27. The method for making a flexible sealed piezoelectric device/sensor of claim 26, wherein the flexible substrate comprises a polymer or plastic coverslip such as a Nunc Thermanox Plastic Coverslip available from Thermo Scientific.

28. The method for making a flexible sealed piezoelectric device/sensor of claim 26, wherein the adhesion layer comprises titanium.

29. The method for making a flexible sealed piezoelectric device/sensor of claim 26, wherein the adhesion layer has a thickness of about 10 nm.

30. The method for making a flexible sealed piezoelectric device/sensor of claim 26, wherein the first electrode layer or first printed circuit board layer comprises gold.

31. The method for making a flexible sealed piezoelectric device/sensor of claim 26, wherein the first electrode layer or the first printed circuit board layer has a thickness of about 100 nm.

32. The method for making a flexible sealed piezoelectric device/sensor of claim 26, wherein the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

33. The method for making a flexible sealed piezoelectric device/sensor of claim 26, wherein the liquid solution of dielectric material comprises polyurethane, or other suitable polymer or a non-polymer material.

34. The method for making a flexible sealed piezoelectric device/sensor of claim 26, wherein the oligopeptide self-assembled monolayer is carboxylate terminated or amide terminated.

35. The method for making a flexible sealed piezoelectric device/sensor of claim 26, wherein the coating is performed by drop casting the liquid solution of dielectric material onto the oligopeptide self-assembled monolayer.

36. The method for making a flexible sealed piezoelectric device/sensor of claim 26, wherein the liquid solution of dielectric material adheres to and attaches the second electrode layer or second printed circuit board layer to the oligopeptide self-assembled monolayer and the first electrode layer or first printed circuit board layer and seals the device/sensor from the atmosphere.

37. A method for making a piezoelectric self-assembling monolayer device, comprising:
forming an oligopeptide self-assembled monolayer on a first conductive layer or a first printed circuit board layer;
coating the oligopeptide self-assembled monolayer with a liquid solution of dielectric material;
placing a second conductive layer or a second printed circuit board layer onto the liquid solution of dielectric material; and
compressing the second conductive layer or the second printed circuit board layer against the liquid solution of dielectric material until the liquid solution of dielectric material dries or cures.

38. The method for making a piezoelectric self-assembling monolayer device of claim 37, wherein the oligopeptide self-assembled monolayer is selected from the group of CA₆, A₆C, CA₉, CA₁₂, CA₇, CA₈, CA₆F, CFA₆, CA₆Y, CYA₆, and CA₆X, where X is the unnatural amino acid cyanophenylalanine.

39. The method for making a piezoelectric self-assembling monolayer device of claim 37, wherein the liquid solution of dielectric material comprises polyurethane or other suitable polymer or a non-polymer material.

40. The method for making a piezoelectric self-assembling monolayer device of claim 37, wherein the oligopeptide self-assembled monolayer is carboxylate terminated or amide terminated.

41. The method for making a piezoelectric self-assembling monolayer device of claim 37, wherein the coating is performed by spraying the liquid solution of dielectric material onto the oligopeptide self-assembled monolayer.

42. The method for making a piezoelectric self-assembling monolayer device of claim 37, wherein the liquid solution of dielectric material adheres to and attaches the second conductive layer or second printed circuit board to the oligopeptide self-assembled monolayer and the first conductive layer or first printed circuit board and seals the device from the atmosphere.
